(19) United States
(12) Patent Application Publication
(10) Pub. No.: US 2008/0135993 A1
(43) Pub. Date: Jun. 12, 2008

(54) Lead frame of through-hole light emitting diode

(75) Inventors: Tien-Fu Huang, Hsinchu (TW); Shyh-Rong Tzan, Hsinchu (TW); Chin-Yin Yu, Hsinchu (TW); Kuo-Chang Hu, Hsinchu (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: Industrial Technology Research Institute, Hsinchu (TW)

(21) Appl. No.: 11/716,457

(22) Filed: Mar. 9, 2007

(30) Foreign Application Priority Data
Dec. 12, 2006 (TW) 095146148

(51) Int. Cl. H01L 23/495

(52) U.S. Cl. 257/673; 257/699; 257/E23.031

(57) ABSTRACT

A lead frame of a through-hole light emitting diode (LED) is used to carry an LED chip, and a lens is used to package the chip and a portion of the lead frame. The lead frame includes at least two leads. One lead is used to carry the chip and each of the leads is extended outward from the lens and has a positioning bump. The positioning bumps partially protrude from the lens, such that when the lead frame is disposed on a circuit board, the lead frame is positioned through the positioning bumps and aligns the lens to guide an optical axis of the through-hole LED, thereby achieving the purposes of convenient assembly, thinness, and a reduced thermal-conducting distance.

### CROSS-REFERENCE TO RELATED APPLICATIONS

This non-provisional application claims priority under 35 U.S.C. §119(a) on Patent Application No(s). 095146148 filed in Taiwan, R.O.C. on Dec. 8, 2006, the entire contents of which are hereby incorporated by reference.

### BACKGROUND OF THE INVENTION

1. Field of Invention

The present invention relates to a lead frame of a light emitting diode (LED), and more particularly, to a lead frame of a thin through-hole LED.

2. Related Art

A lead frame of an LED is used to place an LED chip thereon and through the lead frame, two electrodes of the LED chip are connected to a circuit board, such that the LED is powered on to emit light.

The lead frame of an LED is designed differently depending on various package styles, for example, a conventional, 2-pin, LED (shell-shaped) and a square shaped, 4-pin, through-hole LED (also called anthropophagi, fish LED) have different package methods and different lead frame structures. Here, the package of the anthropophagi fish LED is illustrated as an example. Referring to FIGS. 1, 2A, and 2B at the same time, FIG. 1 is a top view of a conventional lead support 10, and FIGS. 2A and 2B are respectively a top view and a side view of the lead support 10 after being bent. As shown in the figures, the lead support 10 is constituted by a plurality of lead frames 11. As for the package of the anthropophagi fish LED, the lead support 10 is usually formed of fifteen lead frames 11 in the art.

The fabrication flow of the through-hole LED includes the following steps:

(1) firstly punching a carrying portion 13 to form a spoon portion 14; (2) bending the lead support 10 along bending lines 12a and 12b in FIG. 1, so as to form the shapes shown in FIGS. 2A and 2B;

(3) placing an LED chip 15 into the spoon portion 14 shown in the figures and performing wire bonding on electrodes of the LED chip 15 and the lead frames 11, such that the electrodes are electrically connected to leads 16a and 16b, as shown in FIG. 3;

(4) placing the lead support 10 into a die and then encapsulating compound, so as to form a lens 17;

(5) cutting structures 18a, 18b, and 18c, and remaining positioning bumps 19a and 19b, thereby completing the LED of the anthropophagi fish package.

With regard to the usage of the anthropophagi fish LED, referring to FIG. 4, the leads 16a and 16b of the LED are mainly inserted into a circuit board 90, so as to make the positioning bumps 19a and 19b caught onto the circuit board 90 and then soldered to the circuit board. Therefore, through an appropriate design of the positioning bumps 19a and 19b, it can be ensured that a focus optical axis of a focus portion of the lens 17 is perpendicular to the circuit board 90, thereby achieving the purpose of convenient assembly.

Regarding the conventional lead support 10, although the purposes of (a) enhancing the overall structural rigidity of the lead support 10 (through an appropriate design of the structures 18a, 18b, and 18c) and (b) aligning the optical axis are achieved, the thinness requirement of the LED cannot be satisfied. The reason is that a specific distance exists between the positioning bumps 19a, 19b and the lens 17 (formed by cutting the structure 18b), and thus during the soldering process, the distance cannot be eliminated, so the height of the LED after soldering cannot be reduced, resulting in departure from the thinness requirement.

In order to solve the aforementioned problem, one method available in the art is to cut the positioning bumps 19a and 19b and then adjust the perpendicularity of the optical axis before soldering both by hand. Such a method is not only time-consuming, but also rather poor in accuracy and consistency, and thus, it cannot be employed in mass production.

Besides, the leads 16a and 16b further have a thermal-conducting function. However, due to the disposition of the positioning bumps 19a and 19b, the LED chip 15 is far away from the circuit board 90, resulting in a long thermal-conducting distance and poor heat dissipation efficiency. Such a circumstance really cannot cope with the industrial trend that the power of an LED becomes even higher and the heat productivity thereof even greater.

### SUMMARY OF THE INVENTION

In order to solve the aforementioned problems, the present invention provides a lead frame and a lead support of a through-hole LED, so as to facilitate the soldering and assembly, satisfy the requirement of a thin through-hole LED, reduce a thermal-conducting distance, and enhance the heat dissipation efficiency.

The lead frame of a through-hole LED provided by the present invention is used to carry an LED chip and electrically connected to a plurality of electrodes of the LED chip. The LED chip and a portion of the lead frame are encapsulated in a lens which guides a light emitted from the LED chip. The lead frame of the through-hole LED comprises at least two leads. A portion of the leads is encapsulated in the lens and a carrying portion is extended from one of the leads. The carrying portion is encapsulated by the lens and carries the LED chip. The electrodes of the LED chip are electrically connected to the leads, respectively. Each of the leads has a positioning bump. The positioning bumps partially protrude from the lens to constitute a reference plane, which forms a specific angle with the direction of guiding the light.

Secondly, a lead support of a through-hole LED further provided by the present invention is used to carry a plurality of LED chips which are encapsulated by a plurality of lenses, respectively. Edge lines of the encapsulation of the lens form a plurality of lens package lines on the lead support. The lead support of the through-hole LED comprises a plurality of lead frames and a plurality of structures. The structures are connected to the lead frames to form a lead support of the through-hole LED. Each of the lead frames comprises at least two leads and a carrying portion is extended from one of the leads to carry the LED chip. Each of the leads has a positioning bump and at least one lens package line passes through the positioning bumps.

Therefore, the positioning bumps protrude from the lenses appropriately to form a reference plane, such that when a through-hole unit (LED) is inserted in a circuit board, the positioning bumps press against the circuit board to position the through-hole LED. In this manner, the lenses guide the optical axis of the through-hole LED to form a predetermined angle with the circuit board, thereby achieving the purposes of thinness and easy assembly. Furthermore, since the positioning bumps slightly protrude from the lenses, the distance between the LED chips and the circuit board is much smaller than the conventional design, thus reducing the thermal-conducting distance and enhancing the heat dissipation efficiency.

In view of the above, the problems in the prior art can be solved effectively by the technical means provided by the present invention, so as to achieve the purposes of thinness, simple through-hole configuration, and enhancement of the heat dissipation efficiency. Therefore, the technical means of the present invention truly has industrial application, novelty, and is an inventive step.

The features and practice of the preferred embodiments of the present invention will be illustrated below in detail with reference to the drawings.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and thus is not limitative of the present invention, and wherein:

FIG. 1 is a schematic diagram of a conventional lead support of a square shaped, 4-pin, through-hole LED;

FIG. 2A is a top view of the conventional lead support of the LED after being bent;

FIG. 2B is a side view of the conventional lead support of the LED after being bent;

FIG. 3 is a schematic diagram of packaging the conventional lead frame of the LED to a lens;

FIG. 4 is a schematic diagram of soldering the conventional LED to a circuit board;

FIG. 5 is a schematic diagram of a lead support of a through-hole LED according to the present invention;

FIG. 6A is a top view of the lead support of the through-hole LED after being bent according to the present invention;

FIG. 6B is a side view of the lead support of the through-hole LED after being bent according to the present invention;

FIG. 7 is a schematic diagram of packaging the lead frame of the through-hole LED to the lens according to the present invention;

FIG. 8 is a schematic diagram of soldering the lead frame of the through-hole LED to a circuit board according to the present invention;

FIG. 9 is a top view of a lead support of a through-hole LED according to another embodiment of the present invention;

FIG. 10 is a front view of the lead support of the through-hole LED according to another embodiment of the present invention;

FIG. 11 is a right side view of the lead support of the through-hole LED according to another embodiment of the present invention;

FIG. 12 is a schematic diagram of packaging the lead frame of the through-hole LED to a lens according to another embodiment of the present invention; and

FIG. 13 is a schematic diagram of soldering the lead frame of the through-hole LED to a circuit board according to another embodiment of the present invention.

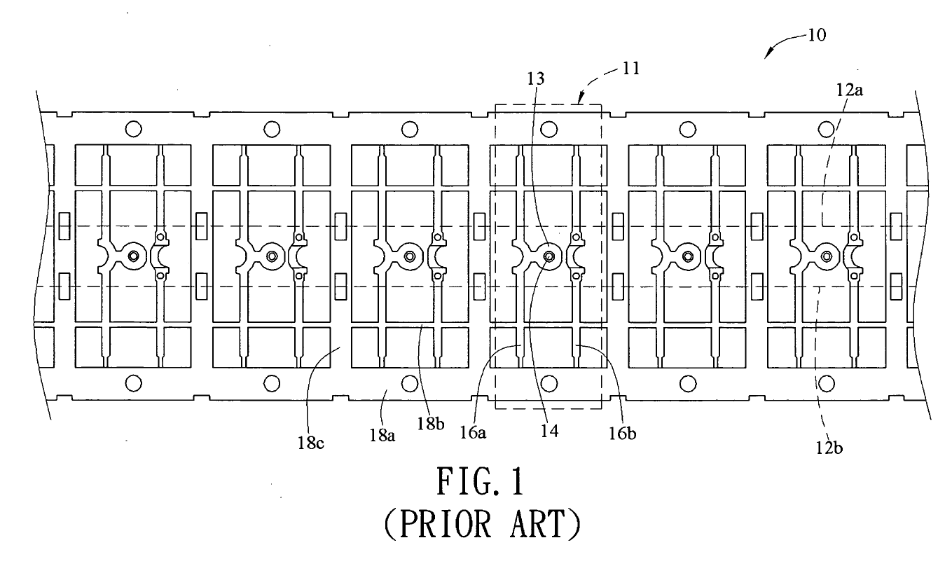

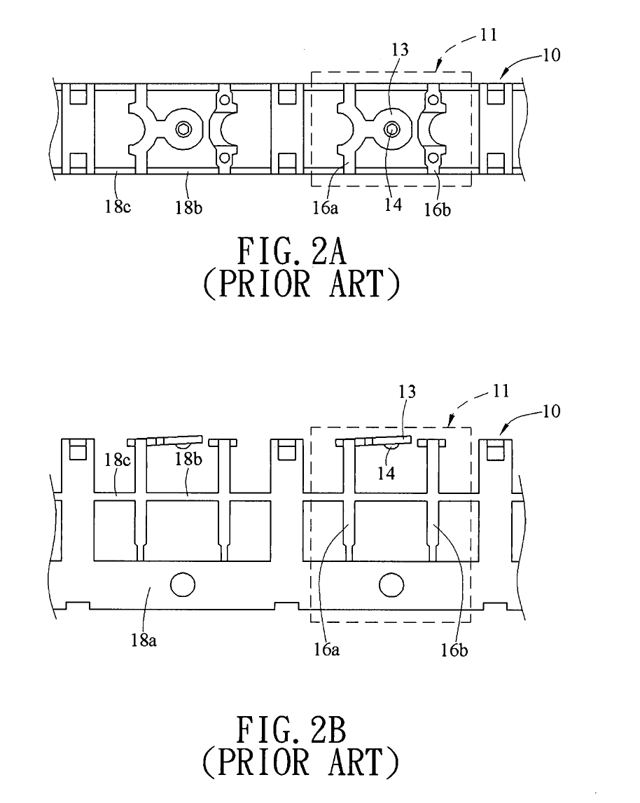

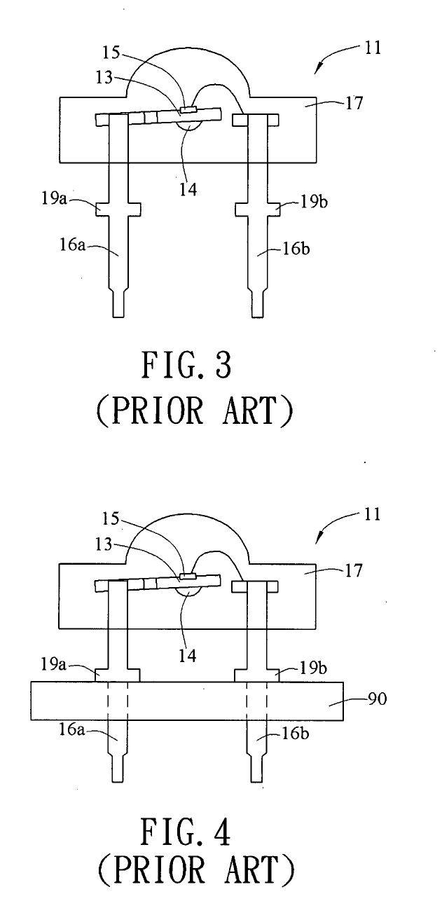

### DETAILED DESCRIPTION OF THE INVENTION

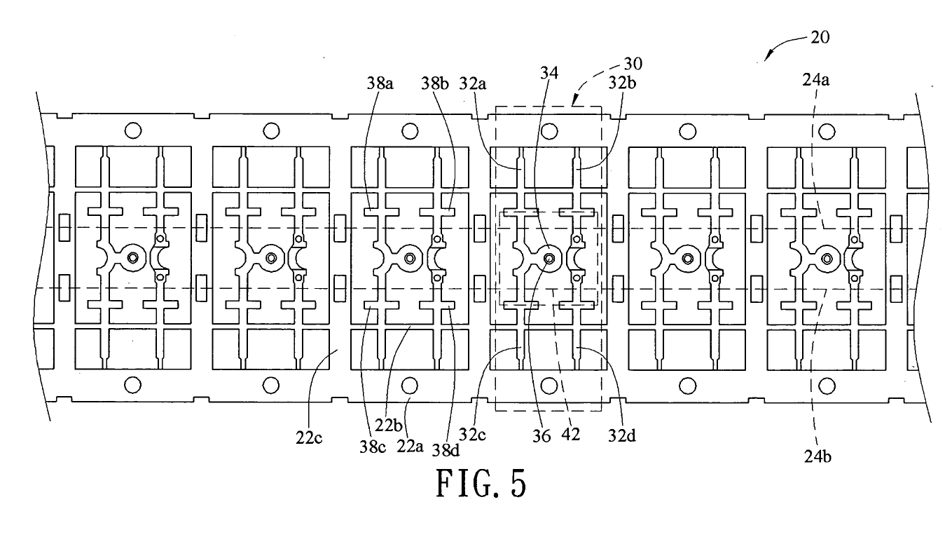

Referring to FIG. 5, a schematic diagram of the lead support of a through-hole LED according to the present invention is shown. As shown in FIG. 5, the lead support 20 of the through-hole LED consists of a plurality of lead frames 30 and a plurality of structures 22a, 22b, and 22c. In the art, a lead support is usually constituted by fifteen lead frames 30 together with a plurality of structures 22a, 22b, and 22c. Of course, herein, the lead support 20 may also be formed of twenty or ten lead frames 30, and the quantity of the lead frames 30 is determined depending on the die of a lens, structural strength, and process conditions. Additionally, the positions of the structures 22a, 22b, and 22c should be determined upon considering the rigidity of the whole lead support 20, such that the lead support 20 may have the functions of providing structural rigidity and bearing the load generated during the processes of chip attachment, wire bonding, mold release and shear of package.

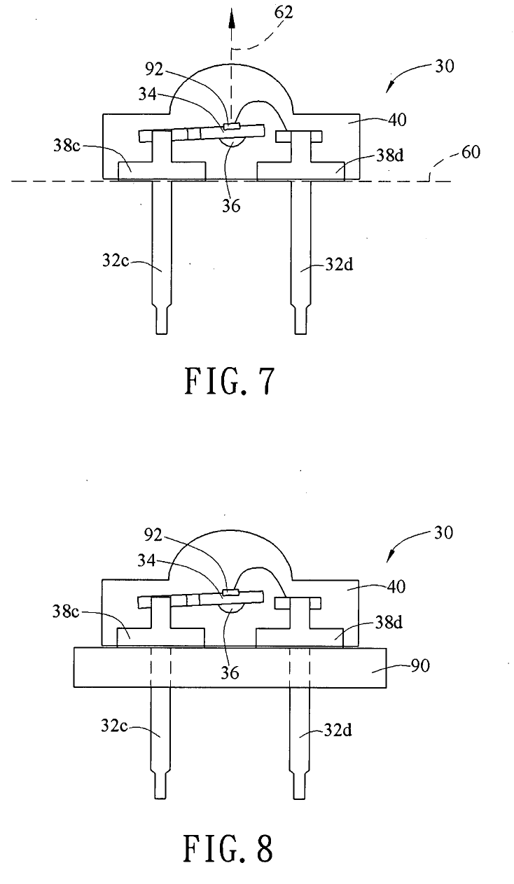

It can be seen from FIG. 5 that each of the lead frames 30 in this embodiment has four leads 32a, 32b, 32c, and 32d. However, the present invention may also be implemented even if there are only three or two leads 32a and 32b, or 32c and 32d in this embodiment, and the leads are soldered to a circuit board (described later). The leads 32a, 32b, 32c, and 32d are disposed symmetrically and any two of the leads are electrically connected with each other, while FIG. 5 merely shows that the leads 32a and 32c are electrically connected with each other and the leads 32b and 32d are electrically connected with each other. A carrying portion 34 is extended from one of the leads 32a, 32b, 32c, and 32d to carry an LED chip 92 (as shown in FIG. 7). In order to make the carrying portion 34 carry the LED chip 92 more stably, a spoon portion 36 is further punched in the carrying portion 34 to accommodate the LED chip. When the LED chip 92 is disposed in the spoon portion 36, a wire bonding operation is performed, such that a plurality of electrodes of the LED chip 92 is electrically connected to the leads 32a, 32b, 32c, and 32d, so as to power on the LED chip 92 through the leads 32a, 32b, 32c, and 32d to emit light.

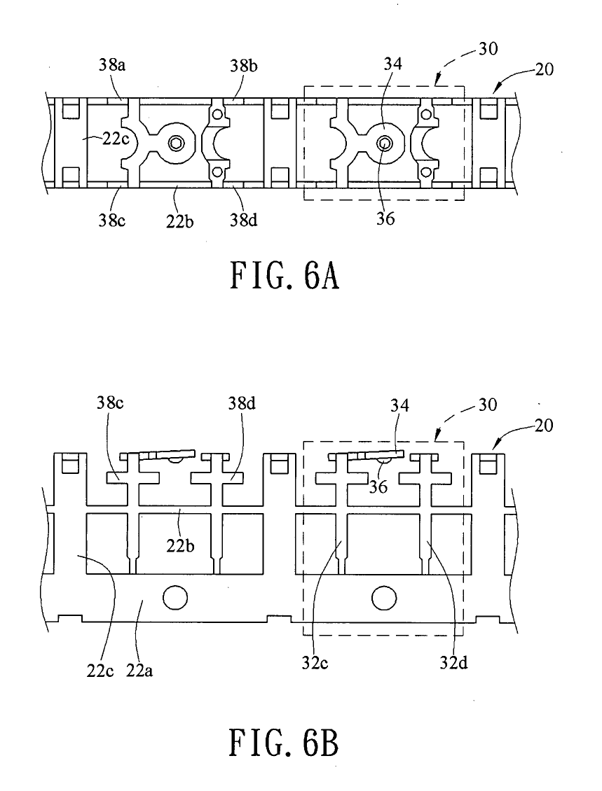

Referring to FIG. 5 again, two bending lines 24a and 24b which are symmetric relative to the carrying portion 34 are shown. Each of the lead frames 30 is bent along the bending lines 24a and 24b to be shaped as shown in FIGS. 6A and 6B. FIG. 6A is a top view after the lead support is bent, and FIG. 6B is a side view after the lead support is bent. The shape of the spoon portion 36 is obviously seen in the figures.

After the lead support 20 is bent, the package and mold release operation of the lens 40 is performed, as shown in FIG. 7. The lens 40 is used to guide the light emitted from the LED chip 92 to be focused or defocused. The package operation of the lens 40 is often performed by means of compound encapsulation.

Referring to FIG. 7, after the package operation of the lens 40 is completed, the structures 22a, 22b, and 22c are sheared off, and only the lead frame 30 is remained. It can be seen from FIG. 7 that the method of shearing off the structures 22a, 22b, and 22c is different from the conventional method. In the present invention, all of the structures are sheared off without remaining any positioning elements in the structures 22a, 22b, and 22c. Instead, the positioning bumps 38a, 38b, 38c, and 38d are disposed at the leads 32a, 32b, 32c, and 32d, respectively. The positioning bumps 38a, 38b, 38c, and 38d are partially merged in the lens 40 while partially exposed outside the lens 40, and the top of the exposed portion of each of the positioning bumps 38a, 38b, 38c, and 38d forms a reference plane 60, as shown in FIG. 7. It can be seen from FIG. 7 that the reference plane is disposed outside of the surface of the lens 40 and forms a specific angle with the direction of the lens guiding a light 62, such as 90° (perpendicular) or 70 to 110°. The degree of the angle is determined depending on the practical application of the LED, i.e., in the range of 70 to 110°. Therefore, when the lead frame 30 is disposed on the circuit board 90, as shown in FIG. 8, the reference plane 60 may serve as a reference of the lead frame 30 being attached to the circuit board 90, such that the optical axis of the light 62 emitted from the LED chip 92 forms a specific angle with the circuit board 90.

Further referring to FIG. 8, it can be seen that the sections of another ends of the leads 32a, 32b, 32c, and 32d opposite to the LED chip 92 are convergent, such that the lead frame 30 can be inserted into the circuit board 90 more easily.

Since the positioning bumps 38a, 38b, 38c, and 38d are disposed on the edge of the lens 40, the distance between the LED chip 92 and the circuit board 90 is smaller than the conventional design, so as to conduct the heat generated by the LED chip 92 more efficiently.

Furthermore, back to FIG. 5, it can be seen that each of the lead frames 30 of the lead support 20 has a lens package line 42 (only one lens package line 42 is shown for simplifying the figure). The lens package line represents a virtual edge line of the lens 40 being packaged after the spoon portion 36 has been punched and the lead frame 30 has been bent, thus forming a closed area. It can be obviously seen from the figure that the lens package line passes through each of the positioning bumps 38a, 38b, 38c, and 38d, and the distances between the positioning bumps 38a, 38b, 38c, and 38d and the lens package line are substantially the same, such that the exceeded (protruding) portions form the aforementioned reference plane to serve as a reference when the lead frame 30 is disposed on the circuit board 90.

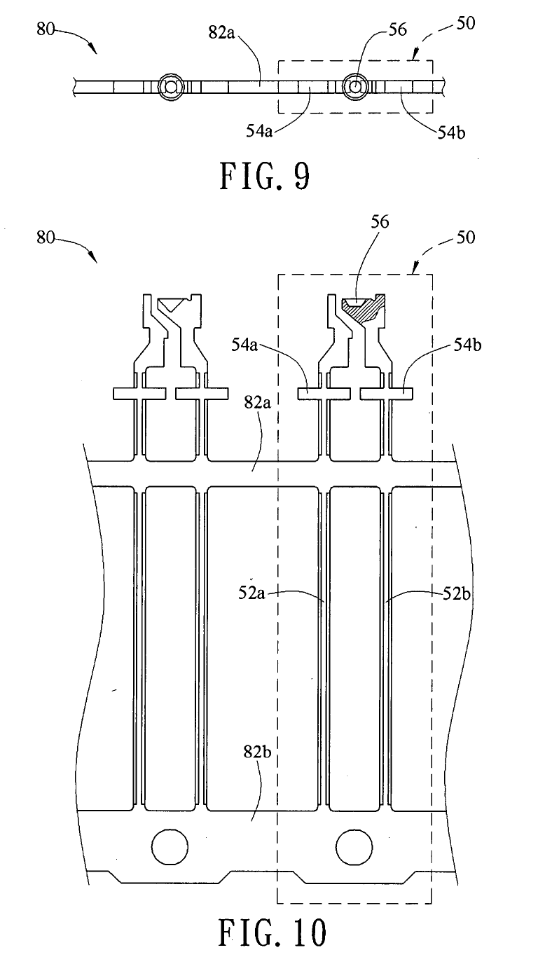

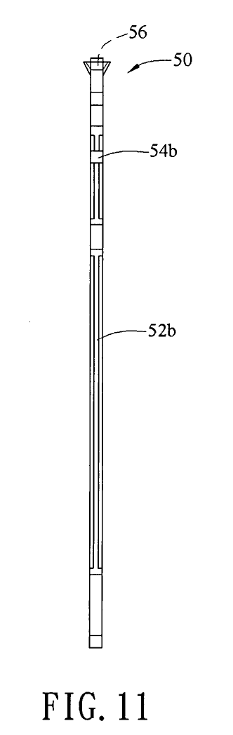

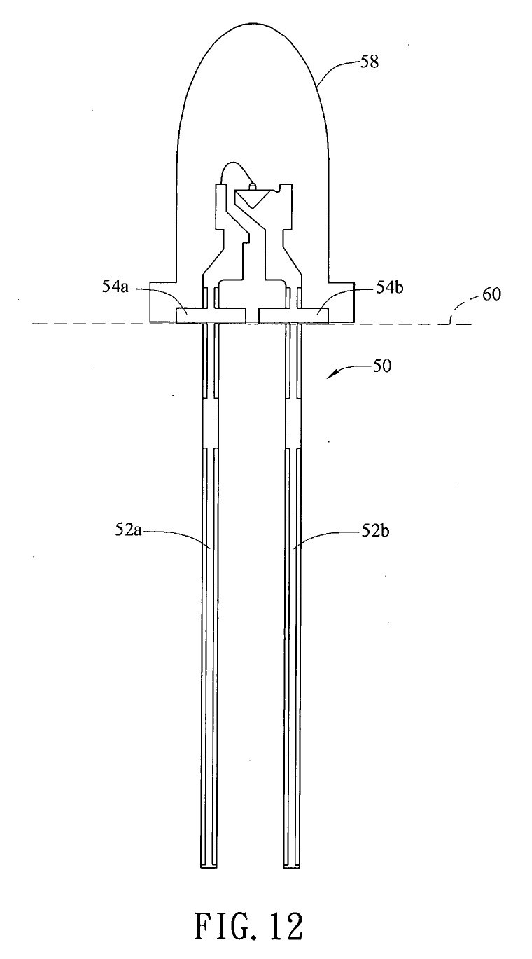

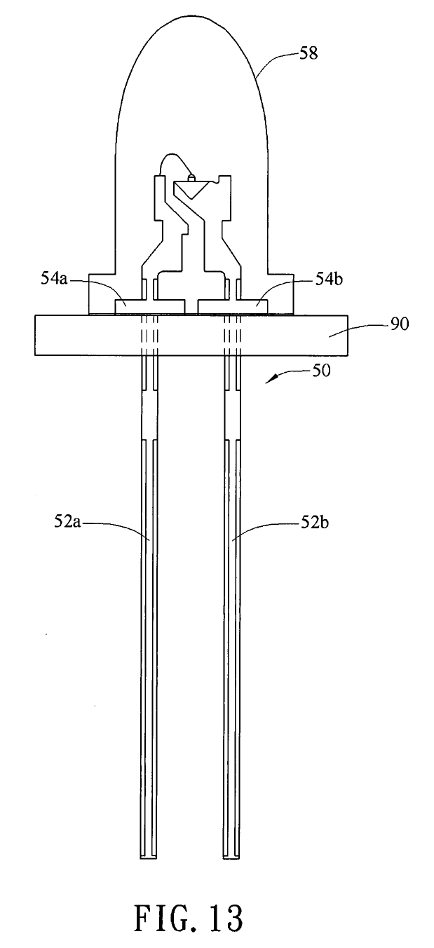

Referring to FIGS. 9, 10, and 11, a top view, a front view, and a right side view of another embodiment of the present invention are shown, respectively. This embodiment is applied to the conventional, 2-pin, LED element (shell-shaped) package. It can be seen from the figures that a lead support 80 consists of a plurality of structures 82a and 82b and a plurality of lead frames 50. Each of the lead frames 50 has two leads 52a, 52b and two positioning bumps 54a, 54b, and a spoon portion 56 is disposed on the top of the lead 52b to accommodate an LED chip (not shown). Referring to FIG. 12, it can be seen from the figure that the positions of the positioning bumps 54a and 54b are just on the surface of a lens 58. The positioning bumps 54a and 54b are partially merged in the lens 58 while partially exposed outside of the lens 58, and the tops of the exposed portions of the positioning bumps 54a and 54b form a reference plane 60. Therefore, when the LED element is disposed on the circuit board 90 (referring to FIG. 13), the exposed tops of the positioning bumps 54a and 54b press against the circuit board 90 to be positioned, so as to achieve the purposes of easy assembly, thinness, and a reduced thermal-conducting distance. Of course, the electrodes of the LED chip in this embodiment should also be electrically connected to the leads 52a and 52b, which is the same as the previous embodiment and will not be repeated herein again.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A lead frame of a through-hole light emitting diode (LED), used to carry an LED chip and electrically connected to a plurality of electrodes of the LED chip, wherein the LED chip and a portion of the lead frame are encapsulated in a lens, and the lens guides a light emitted from the LED chip, the lead frame of the LED comprising:
at least two leads, wherein a portion of the leads is encapsulated in the lens and a carrying portion is extended from one of the leads; the carrying portion is encapsulated by the lens and carries the LED chip; the electrodes of the LED chip are electrically connected to the leads, respectively; each of the leads has a positioning bump; the positioning bumps partially protrude from the lens to constitute a reference plane, and the reference plane forms a specific angle with a direction of guiding the light.

2. The lead frame of a through-hole LED as claimed in claim 1, wherein the reference plane is disposed outside of a surface of the lens.

3. The lead frame of a through-hole LED as claimed in claim 1, wherein the carrying portion has a spoon portion, for accommodating the LED chip.

4. The lead frame of a through-hole LED as claimed in claim 1, wherein the reference plane is perpendicular to the direction of guiding the light.

5. The lead frame of a through-hole LED as claimed in claim 1, wherein the reference plane forms an angle of 70 to 110° with the direction of guiding the light.

6. The lead frame of a through-hole LED as claimed in claim 1, wherein structure of the lead frame comprises four leads disposed symmetrically and any two leads are electrically connected with each other.

7. The lead frame of a through-hole LED as claimed in claim 1, wherein sections of another ends of the leads opposite to the LED chip are convergent.

8. A lead support of a through-hole light emitting diode (LED), used to carry a plurality of LED chips and encapsulate the LED chips with a plurality of lenses, respectively, wherein edge lines of the encapsulation of the lens form a plurality of lens package lines on the lead support, the lead support of the through-hole LED comprising:
a plurality of lead frames, wherein each of the lead frames comprises at least two leads, a carrying portion is extended from one of the leads to carry the LED chip, each of the leads has a positioning bump, and at least one lens package line passes through the positioning bumps; and
a plurality of structures, connected to the lead frames to form the lead support of the through-hole LED.

9. The lead support of a through-hole LED as claimed in claim 8, wherein the carrying portion has a spoon portion, for accommodating the LED chip.

10. The lead support of a through-hole LED as claimed in claim 8, wherein sections of another ends of the leads opposite to the carrying portion are smaller than other portions.

11. The lead support of a through-hole LED as claimed in claim 8, wherein each of the lens package lines forms a closed area.

12. The lead support of a through-hole LED as claimed in claim 11, wherein distances between the positioning bumps penetrated by the same lens package line and the lens package line are same.
